(19) United States
(12) Patent Application Publication
(10) Pub. No.: US 2005/0017301 A1
(43) Pub. Date: Jan. 27, 2005

(54) Semiconductor device having a diffusion layer and a manufacturing method thereof

(75) Inventors: Yasunori Iwatsu, Kanagawa-ken (JP); Koji Shirai, Kanagawa-ken (JP); Yuri Tamura, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 10/793,925

(22) Filed: Mar. 8, 2004

(30) Foreign Application Priority Data
Jul. 25, 2003 (JP) 2003-202131

(51) Int. Cl. H01L 29/76

(52) U.S. Cl. 257/344

(57) ABSTRACT

A semiconductor device having a diffusion layer comprising: a semiconductor substrate of a first conductivity type comprising first and second portions having first and second impurity density, respectively, the first portion located so as to surround the second portion; a transistor having a first diffusion layer and a gate electrode, the first diffusion layer of the transistor formed in the first portion of the semiconductor substrate and having a third impurity density; and a semiconductor well of a second conductivity type formed between the first portion and the second portion of the semiconductor substrate, the semiconductor well having a fourth impurity density and formed so as to surround the first portion of the semiconductor substrate and located in the second portion of the semiconductor substrate.

### CROSS-REFERENCE TO RELATED APPLICATION

This application is based upon and claims the benefit of priority from the prior Japanese Patent Application No.2003-202131, filed Jul. 25, 2003, the entire contents of which are incorporated herein by reference.

### BACKGROUND OF THE INVENTION

1. Field of the Invention

This present invention relates to a semiconductor device having a diffusion layer and a manufacturing method thereof, for example, a MOS transistor and a manufacturing method thereof.

2. Description of the Related Art

It is effective to use two type drains with lower and higher densities in order to alleviate a local electric field around the drains and advance high voltage characteristics of a MOS transistor.

A typical structure for alleviating a local electric field is known as a LDD (Lightly Doped Drain) structure (Japanese Patent Laid Open Hei6-140419). And then, we will explain about the LDD structure of the MOS transistor with the high voltage characteristics with reference to FIG. 11.

FIG. 11 shows a cross sectional view of the conventional LDD structure of the high voltage MOS transistor. As shown in FIG. 11, a N well layer 102 is formed in an element region of a P-type silicon substrate 101. A drain layer 103 of a p-type and a source layer 104 of a P-type are formed in the N well layer 102. A lower impurity diffusion layers 105 and 106 are formed to surround the drain layer 103 and the source layer 104, respectively. A conductivity type of the lower impurity diffusion layers 105 and 106 is a P-type, and also, impurity densities of the lower impurity diffusion layers 105 and 106 are lower than that of the drain layer 103 and the source layer 104.

A channel layer 107 is located between the lower impurity diffusion layers 105 and 106. A silicon oxide layer 108 is formed on the channel layer 107. A gate electrode 109 is formed on the silicon oxide layer 108. And also, a side wall insulating film 110 is formed on a side surface of the gate electrode 109.

FIG. 12 shows an impurity profile of the conventional high voltage MOS transistor along a cross sectional view of an A-A line indicated in FIG. 11. As shown in FIG. 12, a horizontal axis in FIG. 12 shows a depth from an upper surface of the semiconductor substrate, and a vertical axis shows an impurity concentration.

The drain layer 103 is a P-type and includes Boron (B) from 10¹⁸ to 10²⁰/cm³ in impurity density. The lower density diffusion layer 105 formed just under the drain layer 103 is a P-type and includes Boron (B) from 10¹⁶ to 10¹⁷/cm³ in impurity density. An impurity density of the lower density diffusion layer 105 is lower than that of the drain layer 103. An impurity density of the N well 102 formed just under the lower impurity diffusion layer 105 is lower than that of the lower impurity diffusion layer 105. The N well 102 is a N-type and includes Phosphorus (P) of 10¹⁶/cm³ in impurity density. A PN junction is formed by the N well layer 102 and the lower impurity diffusion layer 105.

However, in the conventional high voltage MOS transistor stated above, an impurity density of the lower impurity diffusion layer 105 is higher than that of the N well layer 102. Therefore, when a voltage is applied to the lower impurity diffusion layer 105, a length of a depletion layer that expands toward the N well layer 102 is longer than that of a depletion layer that expands towards the lower impurity diffusion layer 105.

In FIGS. 11 and 12, broken lines show the expansion of the depletion layer in case the voltage is applied. As shown in FIGS. 11 and 12, a X1 indicates the length of the depletion layer that expands towards the lower impurity diffusion layer 105, and also, a X2 indicates the length of the depletion layer that expands toward the N well layer 102. The length of the depletion layer X2 is long, but the length of the depletion layer X1 is very short due to an impurity difference between them.

In case that the length of the depletion layer X1 is shorter, an electrical field around the lower impurity diffusion layer 105 could be concentrated, thereby resulting in an occurrence of an impact ionization. And also, carriers occurred by the impact ionization are accelerated by the electrical field, and more impact ionization is caused by the carriers. Thereby, a large amount of current flows in the semiconductor device, and finally the semiconductor device could be destroyed. This phenomena is called as an avalanche phenomena.

From above reason, it is demanded to alleviate a local electrical field around the drain layer and to prevent the avalanche phenomena from occurring in order to advance the high voltage characteristics.

### SUMMARY OF INVENTION

A first aspect of the present invention is providing a semiconductor device having a diffusion layer comprising: a semiconductor substrate of a first conductivity type comprising first and second portions having first and second impurity density, respectively, the first portion located so as to surround the second portion; a transistor having a first diffusion layer and a gate electrode, the first diffusion layer of the transistor formed in the first portion of the semiconductor substrate and having a third impurity density; and a semiconductor well of a second conductivity type formed between the first portion and the second portion of the semiconductor substrate, the semiconductor well having a fourth impurity density and formed so as to surround the first portion of the semiconductor substrate and located in the second portion of the semiconductor substrate.

A second aspect of the present invention is providing a semiconductor device having a diffusion layer comprising: a first semiconductor substrate of a first conductivity type; a semiconductor well of a second conductivity type having a first impurity density and formed from an upper surface of the first semiconductor substrate to a first predetermined depth; a transistor having a gate electrode and a first diffusion layer of the first conductivity type, the gate electrode formed above the semiconductor well, and the first diffusion layer of the first conductivity type formed in the semiconductor well to be adjacent to the gate electrode; and a second semiconductor substrate of the first conductivity type having a second impurity density lower than the first impurity density of the semiconductor well, the second semiconductor substrate formed in the semiconductor well, below the first diffusion layer, and from the upper surface of the first semiconductor substrate to a second predetermined depth shallower than the first predetermined depth.

A third aspect of the present invention is providing a method for manufacturing a semiconductor device having a diffusion layer, comprising: forming a first impurity layer of a second conductivity type at a first depth in a semiconductor substrate of a first conductivity type; forming a second impurity layer of the second conductivity type from an upper surface of the semiconductor substrate to the upper surface of the first impurity layer so as to make the semiconductor substrate separate into inner and outer portions, an impurity density of the inner portion of the semiconductor substrate being lower than that of the second impurity layer; forming a third impurity layer of the second conductivity type in the inner portion of the semiconductor substrate so as to make the inner portion of the semiconductor substrate separate into first and second portions; forming a channel layer in an upper surface of the third impurity layer between the first and second portions of the semiconductor substrate; forming a gate insulating film on the channel layer; forming first and second diffusion layers of the first conductivity type in the first and second portions of the semiconductor substrate, respectively; and forming a gate electrode on the gate insulating layer.

A fourth aspect of the present invention is providing a method for manufacturing a semiconductor device having a diffusion layer, comprising: forming a semiconductor substrate of a first impurity type, sides and bottom of which are in contact with a semiconductor well of a second impurity type, an impurity density of the semiconductor well being lower than that of the semiconductor substrate; and forming a transistor that has a gate electrode and a first diffusion layer of the first conductivity type, the gate electrode being adjacent to the semiconductor substrate, and the first diffusion layer formed in the semiconductor substrate.

### BRIEF DESCRIPTION OF THE DRAWINGS

FIG. 1 shows a cross sectional view of a semiconductor device having a diffusion layer of a first embodiment in the present invention.

FIG. 2 shows an impurity profile of a semiconductor device having a diffusion layer of a first embodiment in the present invention.

FIG. 3 shows a simulation result in case where a high voltage is applied to a semiconductor device having a diffusion layer of a first embodiment in the present invention.

FIG. 4 shows a first manufacturing step of a semiconductor device having a diffusion layer of a first embodiment in the present invention.

FIG. 5 shows a second manufacturing step of a semiconductor device having a diffusion layer of a first embodiment in the present invention.

FIG. 6 shows a cross sectional view of a semiconductor device having a diffusion layer of a second embodiment in the present invention.

FIG. 7 shows a manufacturing step of a semiconductor device having a diffusion layer of a second embodiment in the present invention.

FIG. 8 shows a cross sectional view of a semiconductor device having a diffusion layer of a third embodiment in the present invention.

FIG. 9 shows a first manufacturing step of a semiconductor device having a diffusion layer of a third embodiment in the present invention.

FIG. 10 shows a second manufacturing step of a semiconductor device having a diffusion layer of a third embodiment in the present invention.

FIG. 11 shows a cross sectional view of a conventional semiconductor device.

FIG. 12 shows an impurity profile of a conventional semiconductor device.

### DETAILED DESCRIPTION OF THE INVENTION

(First Embodiment)

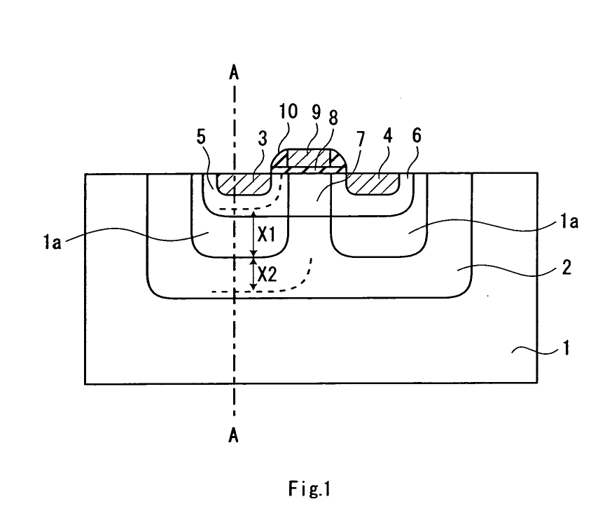

Hereinafter, we will explain about a semiconductor device having a diffusion layer and a manufacturing method of a first embodiment in the present invention with reference to FIGS. 1 to 5. As stated below, a first embodiment of a P-type silicon substrate will be explained. However, an N-type silicon substrate might be used.

First of all, we will explain about a semiconductor device having a diffusion layer of a first embodiment in the present invention with reference to FIG. 1. FIG. 1 shows a cross sectional view of a semiconductor device of the first embodiment in the present invention.

As shown in FIG. 1, an N well layer (a semiconductor region) 2 is located in an upper surface of a P-type silicon substrate. The P-type silicon substrate includes an inner portion 1a and an outer portion 1 (these will be referred to as a P-type silicon substrate collectively). The inner portion 1a of the P-type silicon substrate is located in an upper surface of the N well layer 2 and is surrounded by the N well layer 2. Thereby, the inner portion 1a of the P-type silicon substrate is electrically separated by the other portions of the P-type silicon substrate. A P-type drain layer 3 and a P-type source layer 4 are separately located in an upper surface of the inner portion 1a of the P-type silicon substrate. A lower doped drain layer 5 and a lower source layer 6 are located so as to surround the P-type drain layer 3 and the P-type source layer 4, respectively. The lower doped drain layer 5 and the lower doped source layer 6 have conductivities of a P-type and lower impurity concentrations.

A N-type channel layer 7 is located between the lower doped drain layer 5 and the lower doped source layer 6 in the upper surface of the P-type silicon substrate so as to be adjacent to the N well layer 2. A gate insulating film 8 made of a silicon oxide is located on the channel layer 7. The gate electrode 9 is located on the gate insulating film 8. And also, a side wall insulating layer 10 is located on a side surface of the gate electrode 9.

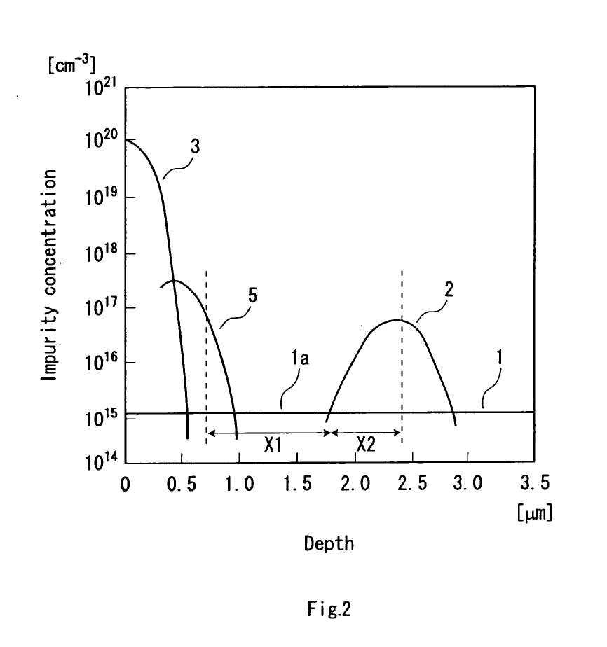

FIG. 2 shows an impurity profile of the semiconductor device having a diffusion layer of the first embodiment in the present invention shown in FIG. 1. FIG. 2 shows the impurity profile along an A-A line in FIG. 1. A horizontal axis of FIG. 2 indicates depth from the upper surface of the P-type silicon substrate. A vertical axis of FIG. 2 indicates an impurity concentration.

A conductivity of the drain layer 3 is a P-type, and the drain layer 3 includes 10¹⁸ to 10²⁰/cm³ of Boron (B) in an impurity density. An impurity density of the lower doped drain layer 5 just under the drain layer 3 is lower than that of the drain layer 3. A conductivity of the lower doped drain layer 5 is also a P-type, and the lower doped drain layer 5 includes 10¹⁶ to 10¹⁷/cm³ of Boron (B) in an impurity density. In this embodiment of the present invention, an impurity profile of the inner portion 1a formed just under the lower doped drain layer 5 is approximately uniform toward a direction of the depth, for instance, about 10¹⁵/cm³ of Boron (B) in an impurity density. The impurity profile of the inner portion 1a, of course, is not limited to this. For instance, the impurity profile of the inner portion 1a could be sloped. A conductivity of the inner portion 1a formed just under the lower doped drain layer 5 is a P-type. A PN junction is constructed by the inner portion 1a of the P-type silicon substrate and the N well 2. And also, the outer portion 1 of the P-type silicon substrate includes 10¹⁵/cm³ of Boron (B) in an impurity density. A conductivity of the outer portion 1 is a P-type. An impurity density of the outer portion 1 is approximately same as that of the inner portion 1a of the P-type substrate.

As shown in FIGS. 1 and 2, broken lines indicate an expansion of a depletion layer in case where a voltage is applied to the drain layer. And also, a X1 in FIGS. 1 and 2 indicates an expansion of a depletion layer toward the drain layer 5 from the PN junction (a boundary between the inner portion 1a and the N well layer 2), and also, a X2 indicates an expansion of a depletion layer toward the outer portion 1 from the PN junction. A conductivity of the inner portion 1a of the P-type silicon substrate is same as that of the drain layer 3 and the lower doped drain layer 5. The inner portion 1a of the P-type substrate, the drain layer 3, and the lower doped drain layer 5 are used as a drain of a transistor.

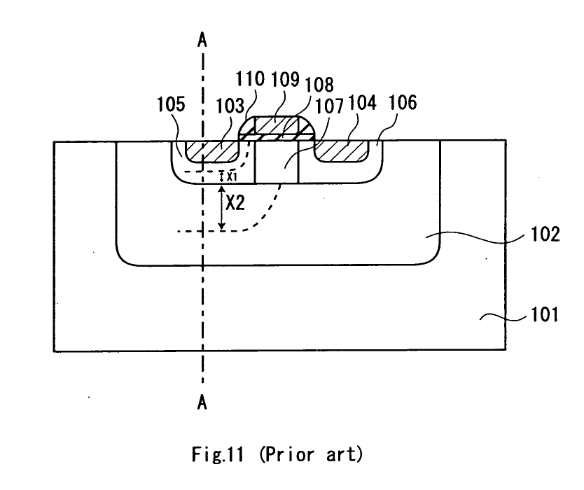

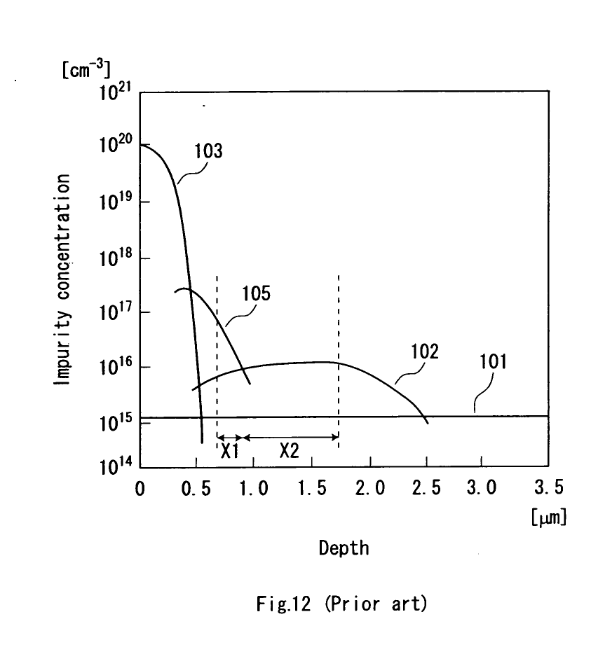

An impurity density of the inner portion 1a of the P-type silicon substrate is lower than that of the N well layer 2 and the lower doped drain 5, and a location of the N well layer 2 is sufficiently deeper than that of the lower doped drain layer 5. Therefore, the length of the depletion layer X1 is longer than the length of the depletion X2. As stated above, the inner portion 1a of the P-type silicon substrate is located between the lower doped drain layer 5 and the N well layer 2, thereby making the depletion layer X1 expanded toward the drain layer 3 and alleviating the local electrical field around the drain layer 5, compared to the conventional high voltage semiconductor device shown in FIGS. 11 and 12.

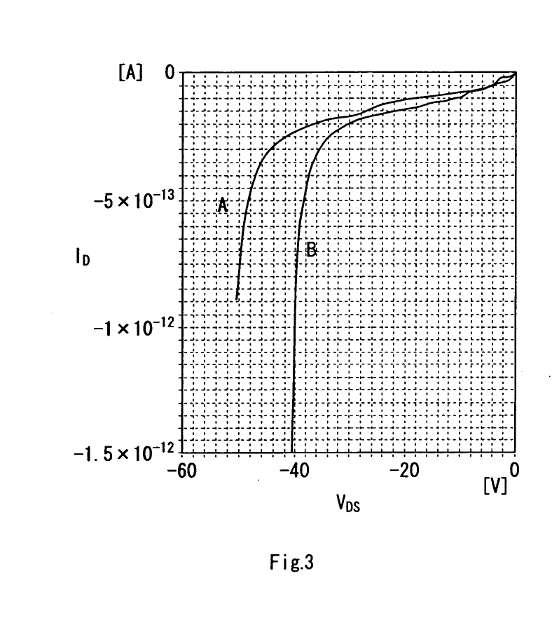

FIG. 3 shows ID v. VDS characteristic (a simulation result in case of VGS=0V) of the high voltage transistor in the first embodiment of the present invention. ID, VDS, and VGS in FIG. 3 indicate a drain current, a voltage between a drain electrode and a source electrode, and a voltage between a gate electrode and a source electrode, respectively. In FIG. 3, a horizontal axis indicates the voltage VDS between the drain electrode and the source electrode, and also, a vertical axis indicates the drain current ID. A solid line “A” in FIG. 3 indicates a drain current characteristic of the high voltage transistor in the first embodiment of the present invention. On the other hand, a solid line “B” in FIG. 3 indicates a drain current characteristic of a conventional high voltage transistor. As shown in FIG. 3, the drain current of the conventional high voltage transistor (the solid line B) increases steeply at or around −30V. However, that of the first embodiment of the present invention does not increase steeply until about −40V. This shows that a high voltage characteristic of the first embodiment in the present invention is greatly advanced, compared to that of the conventional high voltage transistor.

As stated above, in the transistor of the first embodiment in the present invention, the inner portion 1a of the P-type silicon substrate is located between the lower doped drain layer 5 and the N well layer 2. An impurity density of the inner portion 1a is much lower than that of the N well layer 2, thereby expanding a depletion layer toward a drain (the lower doped drain layer 5 and the drain layer 3) and alleviating a local electric field around the drain.

As shown in FIG. 1, the inner portions 1a of the P-type silicon substrate are located at both sides of the channel layer 7. Therefore, a right side and a left side of the P-type silicon substrate may be a drain and a source, respectively. Inversely, a left side and a right side of the P-type silicon substrate may be a drain and a source, respectively.

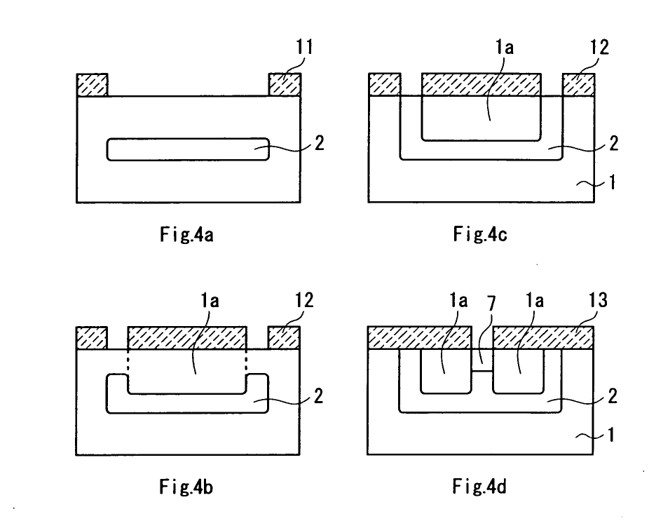

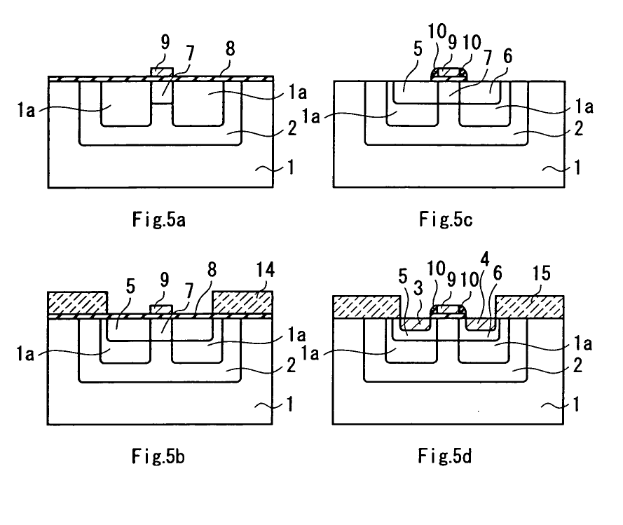

With reference to FIGS. 4 and 5, we will explain about a manufacturing method of the semiconductor device of the first embodiment in the present invention. FIGS. 4 and 5 show cross sectional manufacturing steps of the semiconductor device of the first embodiment in the present invention.

As shown in FIG. 4a, by using a photo lithography technique, a photo resist layer 11 is formed on the P-type silicon substrate so as to be able to form an element region in which a MOS transistor is going to be formed. And then, impurities, for instance, phosphorus (P) are injected at a predetermined depth of the P-type silicon substrate by using an ion injection technique with first injection energy and using the photo resist layer 11 as a mask, thereby forming the N well layer 2. After that, the resist layer 11 is removed.

As shown in FIG. 4b, by using a photo lithography technique, a photo resist layer 12 is formed on the P-type silicon substrate. And then, impurities, for instance, phosphorus (P) are injected by using an ion injection technique with second injection energy lower than the first injection energy, and using the photo resist layer 12 as a mask. The ion injection with the lower injection energy results in injecting the Boron at shallower depth.

As shown in FIG. 4c, impurities, for instance, phosphorus (P) are injected again by using an ion injection technique with third injection energy lower than the second injection energy, thereby forming a N well 2 in the P-type silicon substrate. In a result, there is formed inner portion 1a of the P-type silicon substrate that is separated from an outer portion 1 of the P-type silicon substrate.

As shown in FIG. 4d, by using a photo lithography technique, a photo resist layer 13 is formed on the P-type silicon substrate. Impurities, for instance, phosphorus (P) are injected into the inner portion 1a of the P-type silicon substrate so as to reach an upper surface of the N well layer 2 using the photo resist layer 13 as a mask and using an ion injection technique with same conditions as the second ion injection stated previously. And then, impurities, for instance, phosphorus (P) are injected by using the photo resist layer 13 as a mask and using an ion injection technique, thereby forming a channel layer 7 in an upper surface of the inner portion 1a the P-type silicon substrate. After that, the resist layer 11 is removed.

As shown in FIG. 5a, a silicon oxide layer 8 is formed on the N well 2, the channel layer 7, the inner portions 1a and the outer portion 1 by using, for instance, a thermal oxide method. A poly crystalline silicon layer is formed on the silicon oxide layer. And then the poly crystalline silicon layer is processed in a predetermined patterned, thereby, forming a gate electrode 9.

As shown in FIG. 5b, a photo resist layer 14 is formed on the silicon oxide layer 8. Impurities, for instance, boron (B) are injected into the inner portion 1a of the P-type silicon substrate by using the photo resist layer 14 and the gate electrode 9 as a mask, thereby forming a lower doped drain layer 5 and a lower source layer 6.

As shown in FIG. 5c, the photo resist layer 13 is removed, and a side wall insulating film 10 is formed on the side surface of the gate electrode 9 by using, for instance, a CVD (Chemical Vapor Deposition) method and a RIE (Reactive Ion Etching) method.

As shown in FIG. 5d, a photo resist layer 15 is formed. Impurities, for instance, Boron (B) are injected into the inner portion 1a of the P-type silicon substrate by using the photo resist layer 15, the gate electrode 9, and the side wall insulating film as a mask, thereby forming a drain layer 3 and a source layer 4.

After that, by using a well known method, interlayer insulating layers (not shown), contact holes (not shown), metal lines (not shown), and so on are formed, thereby forming a high voltage MOS transistor.

It should be noted that short annealing time for activating the injected impurities is desirable to prevent the injected impurities from diffusing into the inner portion 1a of the P-type silicon substrate.

As stated above, a plurality of ion injection steps with different ion injection energy are performed in the manufacturing steps of the semiconductor device of the first embodiment in the present invention, thereby remaining the inner portion 1a of the P-type silicon substrate into the N well layer 2.

And also, in case where a P-type diffusion layer with still lower impurity density than the lower doped drain layer 5 is formed under the lower doped drain layer 5, it may be difficult to control the impurity profile of the P-type diffusion layer to be desirable. Therefore, high voltage characteristics of different devices may be different. However, in the manufacturing steps of the semiconductor device of the first embodiment in the present invention, the inner portion 1a of the P-type silicon substrate is formed in the N well layer 2, and the lower doped drain layer 5 and the lower doped source layer 6 are formed. Thereby, an impurity profile in the manufacturing steps of the first embodiment is lower and approximately uniform, thereby preventing the high voltage characteristics from being different.

In the conventional high voltage MOS transistor shown in FIG. 11, it was needed to perform a relatively long time annealing in order to make injected impurities thermally diffused, and form the N well layer 102. However, in the manufacturing method of the first embodiment in the present invention, at least twice ion injections and a relatively short time annealing are performed, thereby forming the N well layer 2. In case where the relatively long time annealing is performed, the injected impurities may be diffused toward not only a direction of a depth but also a direction of a horizon. Therefore, the manufacturing method of the first embodiment in the present invention is suitable for forming down-sized semiconductor elements, compared to the manufacturing method of the conventional high voltage MOS transistor.

In the manufacturing method of the first embodiment in the present invention, the number of ion injections and the accelerated energy of ion injection can be changed to form the N well layer 2, thereby precisely being able to control the depth of the N well layer 2.

It should be noted that the P-type silicon substrate is used for the semiconductor device and the manufacturing method thereof of the first embodiment in the present invention stated above. However, the first embodiment of the present invention is not limited to the P-type. For example, in case where conductivity type of each layer is opposite, an N-type silicon substrate may be used.

And also, injected impurities Boron (B) and Phosphorus (P) are used in the semiconductor device and the manufacturing method thereof of the first embodiment in the present invention stated above. However, of course, they are not limited to them.

In the semiconductor device and the manufacturing method thereof of the first embodiment in the present invention, the source layer 4 and the lower source layer 6 are formed in the inner portion 1a of the P-type silicon substrate. However, the source layer 4 and the lower source layer 6 may be not formed in the inner portion 1a of the P-type silicon substrate.

In the semiconductor device and the manufacturing method thereof of the first embodiment in the present invention, the lower doped drain layer 5 is formed just under the drain layer 3, and the lower doped source layer 6 is formed just under the drain layer 4. However, the lower doped drain layer 5 and the lower doped source layer 6 may not be needed. In other words, in case of any of both the lower doped drain layer 5 and the lower doped source layer 6 are not formed, only the lower doped drain layer 5 is formed, and only the lower doped source layer 6 is formed, the local electric field can be alleviated similar to the case where both the lower doped drain layer 5 and the lower doped source layer 6 are formed.

In the semiconductor device and the manufacturing method thereof of the first embodiment in the present invention, the impurity density of the inner portion 1a of the P-type silicon substrate is same as that of the outer portion 1 of the P-type silicon substrate. However, the first embodiment of the present invention is not limited to this. For example, the inner portion 1a of the P-type silicon substrate may be formed in an epitaxial layer stacked above the outer portion 1 of the P-type semiconductor substrate.

(Second Embodiment)

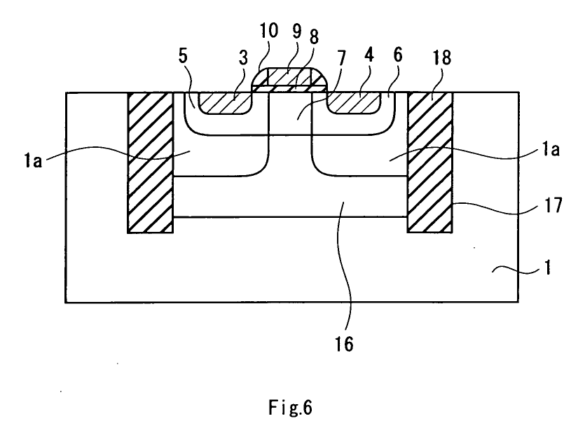

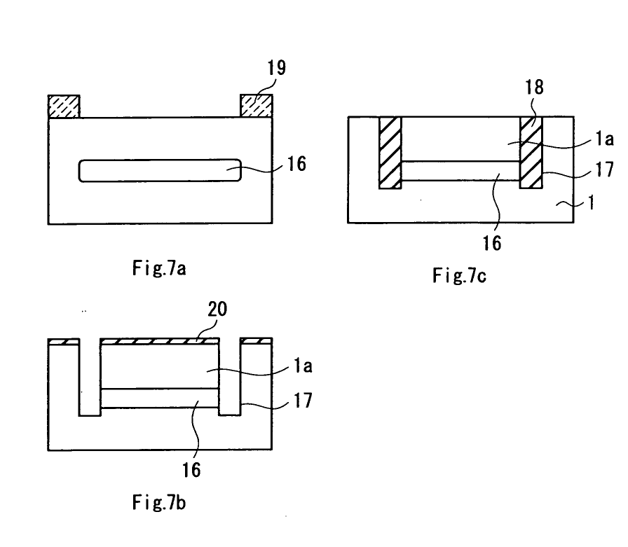

We will explain about a semiconductor device and its manufacturing method of a second embodiment in the present invention with reference to FIGS. 6 and 7. First of all, we will explain about the semiconductor device of the second embodiment in the present invention with reference to FIG. 6.

FIG. 6 shows a cross sectional view of the semiconductor device of the second embodiment in the present invention. It should be noted that a trench isolation technique is applied to the second embodiment in the present invention.

As shown in FIG. 6, an impurity layer 16 of an N-type is formed in an upper surface of a P-type semiconductor substrate. An element isolation insulating layer 18 is formed in an upper surface of the P-type semiconductor substrate. And the element isolation insulating layer 18 is also formed to be contact with the impurity layer 16 and to surround an inner portion 1a of the P-type semiconductor substrate, a drain layer 3, a source layer 4, and a channel layer 7. The element isolation insulating layer 18 is deposited in an element isolation trench 17, thereby surrounding the impurity layer 16 and electrically separating the inner portion 1a of the P-type semiconductor substrate from the other portions of the P-type semiconductor substrate.

In the second embodiment of the present invention, the local electric field around the drain can be alleviated because an impurity density of the inner portion 1a of the P-type semiconductor substrate is lower than that of the impurity layer 16 and the lower doped drain layer 5.

And also, in the second embodiment of the present invention, the silicon oxide layer 18 as the element isolation insulating layer 18 separates electrically the element region from the other portions. A high voltage characteristic among semiconductor devices can be better than that of an element isolation layer formed by the PN junction.

We will explain about the manufacturing method of the second embodiment in the present invention with reference to FIG. 7. FIG. 7 shows cross sectional views of the semiconductor device of the second embodiment in order.

As shown in FIG. 7a, a resist layer 19 patterned is formed on the semiconductor substrate of a P-type by using a photo lithography technique. And then, impurities, for instance, Phosphorus (P) are injected into the semiconductor substrate by using an ion injection with higher injection energy and using the resist layer 19 patterned as a mask, thereby forming the impurity layer 16 in the semiconductor substrate at a predetermined depth. The resist layer 19 patterned is then removed.

As shown in FIG. 7b, a silicon oxide layer 20 is formed on the semiconductor substrate. Portions of the semiconductor substrate are removed so as to reach under a lower surface of the impurity layer 16 by using, for instance, a RIE method and using the silicon oxide layer 20 as a mask, thereby forming an element isolation trench 17 so as to separate an inner portion 1a of the P-type semiconductor substrate from the outer portion 1 of the P-type semiconductor substrate.

As shown in FIG. 7c, a silicon oxide layer 18 is formed by, for instance, a CVD method, and then an upper surface of the silicon oxide layer 18 is removed so as to remain the silicon oxide layer 18 in the element isolation trench 17.

And then, similarly to the first embodiment in the present invention, the manufacturing steps shown in FIG. 4d, and FIGS. 5a to 5d are performed. After that, interlayer insulating layers, contact holes, and electrode lines are formed by the well known techniques. Thereby, the semiconductor device of the second embodiment in the present invention will be provided.

It should be noted that it is desirable to perform an annealing step for short annealing time of period in order to prevent the injected impurities from diffusing into the inner portion 1a of the P-type semiconductor substrate.

In the manufacturing method of the second embodiment in the present invention, the impurity layer 16 is formed by using the ion injection with higher energy, and the element isolation trench 17 is formed so as to surround the impurity layer 16. Thereby, the inner portion 1a of the P-type silicon substrate can be electrically separated from the other portions of the P-type silicon substrate.

In the manufacturing method of the second embodiment of the present invention, if the injection energy with which the impurities are injected is changed, a depth of a boundary between the inner portion 1a and the impurity layer 16 can be controlled well.

The other effects of the manufacturing method of the second embodiment of the present invention are the same as that of the first embodiment. It should be noted that in the semiconductor device and the manufacturing method of the second embodiment, the silicon oxide layer 18 as an insulating layer is fully formed in the element isolation trench 17, but the insulating layer is not limited to the silicon oxide layer 18. For example, a non-doped polycrystalline silicon layer as the insulating layer may be used. In this case, it is desirable to cover an inner-side surface of the element isolation trench 17 with a silicon oxide layer in order to electrically separate elements effectively.

In the semiconductor device and the manufacturing method of the second embodiment in the present invention, the P-type silicon substrate as a semiconductor substrate is used, but the semiconductor substrate is no limited to it. For instance, a N-type silicon substrate as a semiconductor substrate may be used similarly to the first embodiment in the present invention.

In the semiconductor device and the manufacturing method of the second embodiment in the present invention, the boron (B) and the phosphorus (P) as the impurities are used, but the impurities are no limited to those.

In the semiconductor device and the manufacturing method of the second embodiment in the present invention, the source layer 4 and the lower doped layer 6 are formed in the inner portion 1a of the P-type silicon substrate. However, similarly to the first embodiment in the present invention, the source layer 4 and the lower doped layer 6 may not be formed.

In the semiconductor device and the manufacturing method of the second embodiment in the present invention, the lower doped layer 5 just under the source layer 3 and the lower doped layer 6 just under the drain layer 4 are formed. However, similarly to the first embodiment of the present invention, the lower doped layers 5 and 6 may not be formed.

In the semiconductor device and the manufacturing method of the second embodiment in the present invention, an impurity density of the inner portion 1a of the P-type silicon substrate is same as that of the outer portion 1 of the P-type silicon substrate. However, similarly to the first embodiment of the present invention, the present invention is not limited to this.

(Third Embodiment)

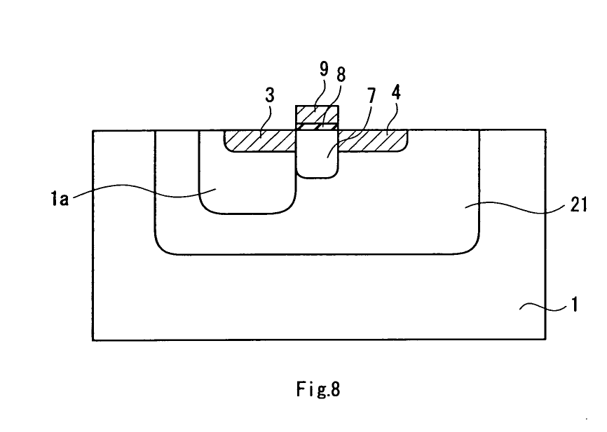

We will explain about a semiconductor device and its manufacturing method of a third embodiment in the present invention with reference to FIGS. 8 to 10. First of all, we will explain about the semiconductor device of the third embodiment in the present invention with reference to FIG. 8.

FIG. 8 shows a cross sectional view of the semiconductor device of the third embodiment in the present invention. As shown in FIG. 8, the semiconductor device in the third embodiment of the present invention has neither an inner portion of the P-type silicon substrate at a source side, a lower doped layer at a drain side, nor a lower doped layer at the source side. The other parts of the third embodiment in the present invention are common to that of the first embodiment in the present invention. Therefore, same references common to FIG. 1 will be assigned and its explanations will be omitted for simplicity.

An N well layer 21 is formed in an upper surface of the P-type semiconductor substrate. An inner portion 1a of the P-type silicon substrate is formed in an upper surface of the P-type silicon substrate so as to be surrounded by the N well layer 21. Thereby, the inner portion 1a of the P-type silicon substrate is electrically separated from the other portions. A drain layer 3 of the P-type is formed in an upper surface of the inner portion 1a of the P-type silicon substrate. A source layer 4 of the P-type is formed so as to be apart form the drain layer 3 in the upper surface of the N well layer 21. A channel layer 7 of N-type is formed between the drain layer 3 and the source layer 4 so as to be contact with the N well layer 21. A silicon oxide layer 8 as a gate insulating film is formed on the channel layer 7, and a gate electrode 9 is formed on the silicon oxide layer 8 as a gate insulating film. In the third embodiment of the present invention, there would be formed the inner portion 1a of the P-type silicon substrate, impurity density of which is lower than that of the N well layer 21, thereby being able to alleviate the local electric field around the drain region.

In the semiconductor device of the third embodiment in the present invention, neither a lower doped drain layer between the drain layer 3 and the channel layer 7 nor a lower doped source layer between the source layer 4 and the channel layer 7 are formed. Therefore, a chip area of the semiconductor device of the third embodiment could be smaller than that of a semiconductor device with the lower doped drain layer and the lower doped source layer.

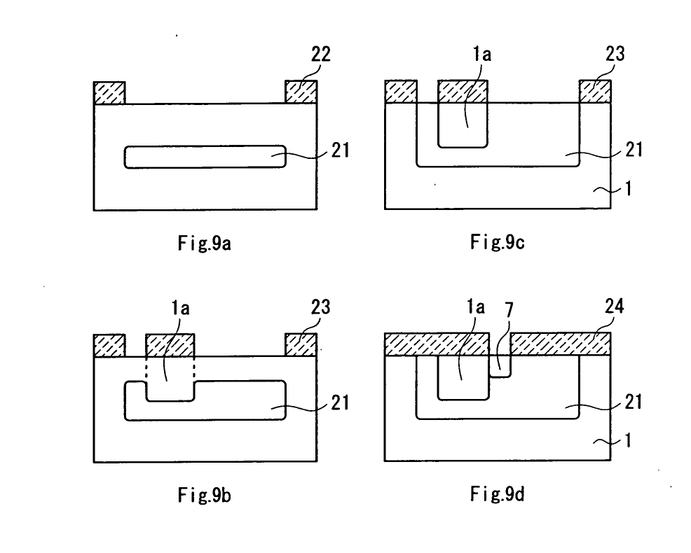

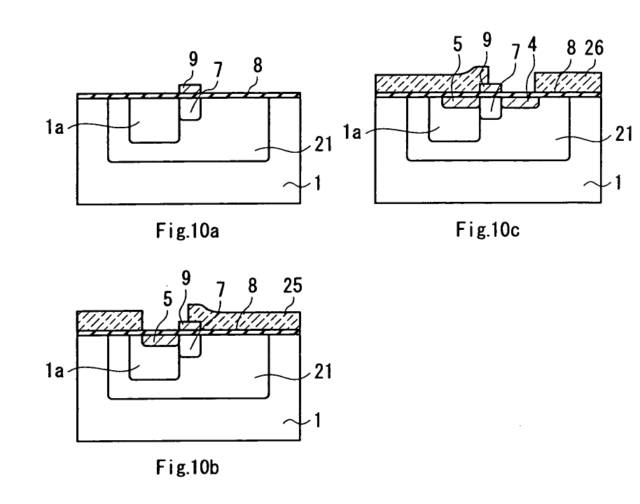

We will explain about the manufacturing method of the third embodiment in the present invention with reference to FIGS. 9 and 10. FIGS. 9 and 10 show cross sectional views of the semiconductor device of the third embodiment in order.

As shown in FIG. 9a, a photo resist layer 22 patterned is formed on the P-type semiconductor substrate by using a photolithography technique. And impurities, for instance, Phosphorus (P) are injected into the P-type semiconductor substrate by using an ion injection technique with high acceleration energy and using the photo resist layer 22 patterned as a mask, thereby forming the impurity layer 21 (which will be the N well layer 21) at a predetermined depth. After that, the photo resist layer 22 is removed.

As shown in FIG. 9b, a photo resist layer 23 patterned is formed on the P-type silicon substrate so as to surround an area to be the inner portion 1a of the P-type silicon substrate by using a photolithography technique. And impurities, for instance, Phosphorus (P) are then injected in the P-type silicon substrate by using an ion injection technique with lower acceleration energy than that of the previous ion injection and using the photo resist layer 23 patterned as a mask.

As shown in FIG. 9c, using the photo resist layer 23 as a mask, an ion injection step with still lower acceleration energy is performed, and the impurities are injected at a shallower position in the P-type silicon substrate, thereby forming the N well layer 21 and separating the inner portion 1a of the P-type silicon substrate from the outer portion 1 of the P-type silicon substrate. After that, the photo resist layer 23 is removed.

As shown in FIG. 9d, a photo resist layer 24 patterned is formed on the P-type silicon substrate by using a photolithography technique. Impurities, for instance, Phosphorus (P) are injected in the P-type silicon substrate by using an ion injection technique and using the photo resist layer 23 as a mask, thereby forming the channel layer 7 in the upper surface of the N well layer 21. After that, the photo resist layer 23 is removed.

As shown in FIG. 10a, the silicon oxide film 8 as the gate insulating film is formed on the P-type silicon substrate by using a thermal oxide method. And then, the gate electrode 9 made by, for instance, a poly crystalline silicon is formed on the silicon oxide film 8.

As shown in FIG. 10b, a photo resist layer 25 is formed on the P-type silicon substrate so as to surround an area to be the drain layer 3. And then, impurities, for instance, Boron (B) is injected into the P-type silicon substrate, thereby forming the drain layer 3 in the P-type silicon substrate by using an ion injection technique and using the photo resist layer 25 as a mask.

As shown in FIG. 10c, a photo resist layer 26 is formed on the P-type silicon substrate by using a photolithography technique. And impurities, for instance, Boron (B) are injected into the upper surface of the P-type silicon substrate by using an ion injection technique and using the photo resist layer 26 as a mask, thereby forming a source layer 4 in the upper surface of the P-type silicon substrate. The photo resist layer 26 is then removed.

After that, interlayer insulting layers (not shown), contact holes (not shown), and electrode lines (not shown) are formed by using a well known technique, thereby forming the semiconductor device of the third embodiment in the present invention.

It should be noted that it is desirable to perform an annealing step for short annealing time of period in order to prevent the injected impurities from diffusing into the inner portion 1a of the P-type semiconductor substrate.

As stated above, similarly to the first embodiment, a plurality of ion injection steps with different ion injection energy are performed in the manufacturing steps of the semiconductor device of the third embodiment in the present invention, thereby remaining the inner portion 1a of the P-type silicon substrate into the N well layer 2.

Similarly to the first embodiment, in the manufacturing method of the third embodiment in the present invention, the number of ion injection steps and the accelerated energy of ion injection can be changed to form the N well layer 2, thereby being able to precisely control the depth of the N well layer 2.

The other effects of the manufacturing method of the third embodiment of the present invention are the same as that of the first embodiment of the present invention.

It should be noted that, in the semiconductor device and the manufacturing method thereof, the P-type silicon substrate is used as a silicon substrate, but the silicon substrate is not limited to it. Similarly to the first embodiment in the present invention, the silicon substrate may be a N-type silicon substrate.

In the semiconductor device and the manufacturing method of the third embodiment in the present invention, the Boron (B) and the Phosphorus (P) as the impurities are used, but the impurities are no limited to those.

In the semiconductor device and the manufacturing method of the third embodiment in the present invention, the lower doped drain layer 5 (stated in the first embodiment in the present invention) between the channel layer 7 and the drain layer 3 is not formed, but the lower doped drain layer 5 may be formed therebetween.

Similarly, in the semiconductor device and the manufacturing method of the third embodiment in the present invention, the lower doped drain layer 6 (stated in the first embodiment in the present invention) between the channel layer 7 and the source layer 4 is not formed, but the lower doped source layer 6 may be formed therebetween.

In the semiconductor device and the manufacturing method thereof of the third embodiment in the present invention, the impurity density of the inner portion 1a of the P-type silicon substrate is same as that of the outer portion 1 of the P-type silicon substrate. However, the third embodiment of the present invention is not limited to this.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended and their equivalents.

1. A semiconductor device having a diffusion layer comprising:
a semiconductor substrate of a first conductivity type comprising first and second portions having first and second impurity density, respectively, the first portion located so as to surround the second portion;
a transistor having a first diffusion layer and a gate electrode, the first diffusion layer of the transistor formed in the first portion of the semiconductor substrate and having a third impurity density; and
a semiconductor well of a second conductivity type formed between the first portion and the second portion of the semiconductor substrate, the semiconductor well having a fourth impurity density and formed so as to surround the first portion of the semiconductor substrate and located in the second portion of the semiconductor substrate.

2. The semiconductor device having a diffusion layer according to claim 1, the third impurity density of the first diffusion layer of the transistor is higher than the first impurity density of the first portion of the semiconductor substrate.

3. The semiconductor device having a diffusion layer according to claim 1, the fourth impurity density of the semiconductor well is higher the first impurity density of the first portion of the semiconductor substrate.

4. The semiconductor device having a diffusion layer according to claim 1, the fourth impurity density of the semiconductor well is higher the second impurity density of the second portion of the semiconductor substrate.

5. The semiconductor device having a diffusion layer according to claim 1, further comprising a channel diffusion layer formed in the semiconductor well and below the gate electrode to be adjacent to the first diffusion layer of the first conductivity type.

6. The semiconductor device having a diffusion layer according to claim 1, a distribution of impurity density of the first portion of the semiconductor substrate is approximately uniform toward a depth direction.

7. The semiconductor device having a diffusion layer according to claim 1, an element insulating layer formed to surround the transistor.

8. The semiconductor device having a diffusion layer according to claim 1, a second diffusion layer of the first conductivity type formed below the first diffusion layer, an impurity density of the second diffusion layer being lower than that of the first diffusion layer.

9. A semiconductor device having a diffusion layer comprising:
a first semiconductor substrate of a first conductivity type;
a semiconductor well of a second conductivity type having a first impurity density and formed from an upper surface of the first semiconductor substrate to a first predetermined depth;
a transistor having a gate electrode and a first diffusion layer of the first conductivity type, the gate electrode formed above the semiconductor well, and the first diffusion layer of the first conductivity type formed in the semiconductor well to be adjacent to the gate electrode; and
a second semiconductor substrate of the first conductivity type having a second impurity density lower than the first impurity density of the semiconductor well, the second semiconductor substrate formed in the semiconductor well, below the first diffusion layer, and from the upper surface of the first semiconductor substrate to a second predetermined depth shallower than the first predetermined depth.

10. The semiconductor device having a diffusion layer according to claim 9, further comprising a channel layer formed in the semiconductor well and below the gate electrode to be adjacent to the first diffusion layer of the first conductivity type.

11. The semiconductor device having a diffusion layer according to claim 9, a distribution of impurity density of the second semiconductor substrate of the first conductivity type is uniform toward a depth direction.

12. The semiconductor device having a diffusion layer according to claim 9, further comprising an element insulating layer formed to surround the transistor.

13. The semiconductor device having a diffusion layer according to claim 9, further comprising a second diffusion layer of the first conductivity type formed below the first diffusion layer and having a third predetermined depth shallower than the second predetermined depth of the a second semiconductor substrate, an impurity density of the second diffusion layer being lower than that of the first diffusion layer and the second semiconductor substrate.

14. A method for manufacturing a semiconductor device having a diffusion layer, comprising:
forming a first impurity layer of a second conductivity type at a first depth in a semiconductor substrate of a first conductivity type;
forming a second impurity layer of the second conductivity type from an upper surface of the semiconductor substrate to the upper surface of the first impurity layer so as to make the semiconductor substrate separate into inner and outer portions, an impurity density of the inner portion of the semiconductor substrate being lower than that of the second impurity layer;
forming a third impurity layer of the second conductivity type in the inner portion of the semiconductor substrate so as to make the inner portion of the semiconductor substrate separate into first and second portions;
forming a channel layer in an upper surface of the third impurity layer between the first and second portions of the semiconductor substrate;
forming a gate insulating film on the channel layer;
forming first and second diffusion layers of the first conductivity type in the first and second portions of the semiconductor substrate, respectively; and
forming a gate electrode on the gate insulating layer.

15. The method for manufacturing a semiconductor device having a diffusion layer according to claim 14, further comprising: forming third and fourth diffusion layers of the first conductivity type in the first and second portions of the semiconductor substrate, respectively, impurity densities of the third and fourth diffusion layers being higher than that of the first and second diffusion layers.

16. The method for manufacturing a semiconductor device having a diffusion layer according to claim 14, further comprising: forming an element insulating layer formed to surround the gate electrode, the first and second diffusion layers.

17. The method for manufacturing a semiconductor device having a diffusion layer according to claim 14, further comprising: forming a side wall insulating film on a side of the gate electrode.

18. A method for manufacturing a semiconductor device having a diffusion layer, comprising:
forming a semiconductor substrate of a first impurity type, sides and bottom of which are in contact with a semiconductor well of a second impurity type, an impurity density of the semiconductor well being lower than that of the semiconductor substrate; and
forming a transistor that has a gate electrode and a first diffusion layer of the first conductivity type, the gate electrode being adjacent to the semiconductor substrate, and the first diffusion layer formed in the semiconductor substrate.

19. The method for manufacturing a semiconductor device having a diffusion layer according to claim 18, further comprising: forming a channel layer of the first conductivity type below the gate electrode of the transistor.

20. The method for manufacturing a semiconductor device having a diffusion layer according to claim 18, further comprising: forming an element insulating layer so as to surround the transistor.

21. The method for manufacturing a semiconductor device having a diffusion layer according to claim 18, further comprising: forming a second diffusion layer of the first conductivity type, an impurity density of the second diffusion layer being lower than that of the first diffusion layer.

22. The method for manufacturing a semiconductor device having a diffusion layer according to claim 18, further comprising: forming a side wall insulating film on a side of the gate electrode.

23. The method for manufacturing a semiconductor device having a diffusion layer according to claim 18, further comprising: forming a channel layer of the first conductivity type in the semiconductor well of the second impurity type.
